(19) United States
(12) Patent Application Publication
(10) Pub. No.: US 2005/0056907 A1
(43) Pub. Date: Mar. 17, 2005

(54) Power transistor and semiconductor integrated circuit using the same

(76) Inventor: Teruyuki Maeda, Sakurai-shi (JP)

Correspondence Address: EDWARDS & ANGELL, LLP, P.O. BOX 55874, BOSTON, MA, 02205, US

(21) Appl. No.: 10/735,399

(22) Filed: Dec. 11, 2003

(30) Foreign Application Priority Data
Dec. 11, 2002 (JP) 2002-359117
Dec. 3, 2003 (JP) 2003-404517

(51) Int. Cl. H01L 29/00

(52) U.S. Cl. 257/500

(57) ABSTRACT

There is provided a power transistor, as well as a semiconductor integrated circuit using the power transistor, in which malfunctions of parasitic PNP transistor and circuit malfunctions due to latch-up of peripheral circuits can be prevented. In a power transistor composed of a plurality of vertical PNP transistors arrayed on a P-type silicon substrate, a singularity or plurality of electrode portions of an N⁺ type buried layer formed to isolate the P-type silicon substrate and collectors of the plurality of vertical PNP transistors from each other are provided in an active region of the power transistor.

### BACKGROUND OF THE INVENTION

The present invention relates to a power transistor and a semiconductor integrated circuit using the same. More particularly, the invention relates to a power transistor, as well as a semiconductor integrated circuit using the same, in which a plurality of vertical PNP transistors are arrayed.

Conventionally, there has been provided a power transistor in which a plurality of vertical PNP transistors are arrayed on a semiconductor substrate (see, for example, Japanese Patent Laid-Open Publication HEI 7-183311).

FIG. 3 shows a pattern plan view of a conventional power transistor, and FIG. 4 shows a sectional view taken along the line IV-IV of FIG. 3. In this power transistor, there are formed, on a P-type silicon substrate 101: an N⁺ type buried layer 102 for isolating the P-type silicon substrate 101 and a collector of each vertical PNP transistor from each other; a P⁺ type collector buried layer 103 which is formed on the N⁺ type buried layer 102 and which serves as the collector of each vertical PNP transistor; a P⁺ type buried isolation layer 113 formed around the N⁺ type buried layer 102 to isolate the power transistor and its peripheral devices from each other; an N-type epitaxial layer 104 formed all over the surface of the P-type silicon substrate 101 by N-type epitaxial growth; an N⁺ type base well layer 105 formed as a base region of each vertical PNP transistor to improve the transistor characteristics; a P⁺ type collector layer 106 formed on the P⁺ type collector buried layer 103; a P⁺ type isolation layer 116 formed at an upper portion of the P⁺ type buried isolation layer 113 serving for device isolation; a P⁺ type emitter layer 107 serving as an emitter of each vertical PNP transistor formed within the region of the N⁺ type base well layer 105; an N⁺ type base layer 108 formed in the base electrode region of each vertical PNP transistor; and an N⁺ type electrode layer 118 which is formed so as to surround the P⁺ type collector layer 106 for taking the electrode of the N⁺ type buried layer 102 located just under the power transistor region. Also, a selectively patterned and opened oxide film 120 is formed on the surface of the P-type silicon substrate 101, and further thereon are formed common emitter metal lines 109, common base metal lines 110 and common collector metal lines 111 routed for electrical connections among a plurality of unit transistors constituting the power transistor, as well as metal lines 112 of the N⁺ type buried layer 102 connected to the common emitter metal lines 109 and grounded to GND. It is noted that all of these are formed by a known standard bipolar IC manufacturing method. In FIG. 3, since the common base metal lines 110 are of less importance for the present invention, their interconnect lines are partly omitted.

With the structure of this conventional power transistor, there has been a problem that with the vertical PNP transistors in the saturation region, the parasitic PNP transistor would malfunction, causing leak currents to flow to the P-type silicon substrate, so that the voltage level of the P-type silicon substrate would be unstable, causing latch-up of peripheral circuits of the power transistor, which would lead to circuit malfunctions. The mechanism of occurrence of leak currents with the vertical PNP transistors in the saturation region is explained below by using part of the cross-sectional structure of the power transistor.

FIG. 5 is a sectional view of the power transistor with the vertical PNP transistors in the saturation region, where while the vertical PNP transistors are in the saturation region, the common emitter metal lines 109 and the metal lines 112 of the N⁺ type buried layer 102 routed and connected with the common emitter metal lines 109 are given a voltage of 0 V, the common base metal lines 110 are given a voltage of −0.6 V, and the common collector metal lines 111 are given a voltage of −0.3 V. It is noted that in FIG. 5, solid-line arrows represent holes and broken-line arrows represent electrons.

First, as an input current of the vertical PNP transistors, holes are injected from the P⁺ type emitter layer 107 into the N⁺ type base well layer 105, making a base current flow (represented by solid-line arrow A in FIG. 5). With the vertical PNP transistors in the saturation region, the P⁺ type collector buried layer 103 and the N⁺ type base well layer 105 have a forward bias of 0.3 V applied therebetween, so that electrons are injected from the N⁺ type base well layer 105 to the P⁺ type collector buried layer 103 (represented by broken-line arrow B in FIG. 5).

Then, part of the injected electrons reach up to the N⁺ type buried layer 102, where those are recombined and dissipated (broken-line arrow C in FIG. 5). In this case, since the N⁺ type buried layer 102 are routed and connected to the common emitter metal lines 109 and grounded to GND by the metal lines 112 via its own resistance R1 and the resistance R2 of the N-type epitaxial layer 104, the large values of the resistance R1 and resistance R2 would cause part of the injected electrons to return to the P⁺ type collector buried layer 103 without recombining (broken-line arrow C′ in FIG. 5).

By the electrons that have returned to the P⁺ type collector buried layer 103 without recombining, holes are injected from the P⁺ type collector buried layer 103 into the N⁺ type buried layer 102 (solid-line arrow D in FIG. 5). With causing the voltage of the N⁺ type buried layer 102 to lower, a hole current is hFE-multiplied by the parasitic PNP transistor (a transistor comprised of the P⁺ type collector buried layer 103 as an emitter, the N⁺ type buried layer 102 as a base and the P-type silicon substrate 101 as a collector), thus flowing as a leak current through the P-type silicon substrate 101 (solid-line arrow E in FIG. 5).

In this conventional power transistor, as shown in FIG. 4, since electrode portions of the N⁺ type buried layer 102 (pattern region of the N⁺ type electrode layer 118) are provided so as to surround the active region of the power transistor, the distance from the N⁺ type buried layer 102 just under central portion of the power transistor to the electrode portion becomes a long one so that the resistance R1 becomes very large. Thus, there has been a problem that with the power transistor in the saturation region, the parasitic PNP transistor would be more likely to malfunction, causing a leak current to flow to the P-type silicon substrate 101.

These problems are critical problems that could resultantly cause voltage level of the P-type silicon substrate 101 unstable, leading to occurrence of latch-up of peripheral circuits of the power transistor, and thus to circuit malfunctions.

### SUMMARY OF THE INVENTION

Accordingly, an object of the present invention is to provide a power transistor, as well as a semiconductor integrated circuit using the power transistor, in which malfunctions of the parasitic PNP transistor of the power transistor are suppressed so that circuit malfunctions due to latch-up of the peripheral circuits are prevented.

In order to achieve the above object, according to the present invention, there is provided a power transistor composed of a plurality of vertical PNP transistors formed on a P-type silicon substrate, wherein a singularity or plurality of electrode portions of an N⁺ type buried layer formed to isolate the P-type silicon substrate and the plurality of vertical PNP transistors from each other are provided in an active region of the power transistor.

In this power transistor, by the provision of one or more electrode portions of the N⁺ type buried layer within the power-transistor active region, the distance from the N⁺ type buried layer just under the power transistor to the electrode portions becomes shorter, and so the resistance thereof becomes smaller. Thus, malfunctions of the parasitic PNP transistors can be prevented, and circuit malfunctions due to latch-up of the peripheral circuits of the power transistor can be prevented.

In one embodiment, at least part of the electrode portion is provided under common emitter metal lines of the power transistor routed on the active region of the power transistor.

In the power transistor of this embodiment, by the provision of the electrode portions of the N⁺ type buried layer under the common emitter metal lines of the power transistor formed and routed on the power-transistor active region, effective use of the limited design space of the power transistor can be made without increasing the power transistor size, thus making it unnecessary to make complex pattern design.

Also, in one embodiment, the electrode portions are provided on the N⁺ type buried layer and formed of an N⁺ type electrode layer for making ohmic contact and an N⁺ type diffusion layer.

Whereas the primary cause of malfunctions of the parasitic PNP transistors is that the resistance component of the N⁺ type buried layer is large, the resistance of the N-type epitaxial layer present longitudinally from the N⁺ type electrode layer to the N⁺ type buried layer provided at the bottom face of the power transistor is another cause, which is less influential as it is. Thus, according to the power transistor of this embodiment, an N⁺ type diffusion layer heavier in dopant level than the N-type epitaxial layer is formed at the electrode portions of the N⁺ type buried layer, by which the resistance of up to the N⁺ type buried layer can be reduced, so that malfunctions of the parasitic PNP transistors can be prevented.

Also, in one embodiment, the N⁺ type diffusion layer is formed simultaneously with an N⁺ type base well layer as a base region of the plurality of vertical PNP transistors.

In the power transistor of this embodiment, the N⁺ type base well layer, which is needed for characteristic improvement of the vertical PNP transistors and formed over the base region of the vertical PNP transistors, and the N⁺ type diffusion layer are formed simultaneously. Thus, it becomes possible to lessen the resistance of the N-type epitaxial layer without involving any additional process.

Also, in one embodiment, the N⁺ type diffusion layer is formed at a range of dopant level of 1×10¹⁶ to 1×10¹⁷ atoms/cm³, which is heavier than that of an N-type epitaxial layer formed on the P-type silicon substrate.

In the power transistor of this embodiment, the practical-use range of dopant level of the N⁺ type diffusion layer is set heavier than that of the N-type epitaxial layer and such light as not to affect the characteristic of the vertical PNP transistors. In consideration of this, the practical-use range of dopant level is preferably 1×10¹⁶ to 1×10¹⁷ atoms/cm³. As a result of this, the longitudinally-present resistance of the N-type epitaxial layer can be reduced.

Also, in one embodiment, the N⁺ type diffusion layer is formed so that dopants are diffused until they reach the N⁺ type buried layer present on a bottom face of the power transistor.

In the power transistor of this embodiment, the N⁺ type diffusion layer is formed so as to be diffused until it reaches the N⁺ type buried layer provided at the bottom face of the power transistor. Thus, the resistance of the N-type epitaxial layer can be reduced, and it never occurs that the resistance increases while the N-type epitaxial layer remains.

Also, in one embodiment, the singularity or plurality of electrode portions are placed so as to be uniformly spaced from their respectively adjacent electrode portions.

In the power transistor of this embodiment, a plurality of electrode portions are placed so as to be uniform in distance to their respectively adjacent electrode portions of the N⁺ type buried layer, so that the resistance of the N⁺ type buried layer just under the power-transistor active region can be made smaller, so that the resistance distribution of the buried layer can be uniformized, thus making it possible to suppress the occurrence of local leak currents. Further, although depending on the resistance value of the N⁺ type buried layer, hFE of the parasitic PNP transistors, and the like, the number of placed electrode portions of the N⁺ type buried layer, if required, can be increased to reduce the resistance.

Furthermore, according to the present invention, there is provided a semiconductor integrated circuit which uses any one of the power transistors as described above.

In this semiconductor integrated circuit, a power transistor that can be prevented from malfunctions of the parasitic PNP transistors and circuit malfunctions due to latch-up of the peripheral circuits is used. Thus, there can be provided a high-performance semiconductor integrated circuit capable of stable operation.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a plan view of a power transistor according to an embodiment of the present invention;

FIG. 2 is a sectional view taken along the line II-II of FIG. 1;

FIG. 3 is a pattern plan view of a power transistor according to a prior art;

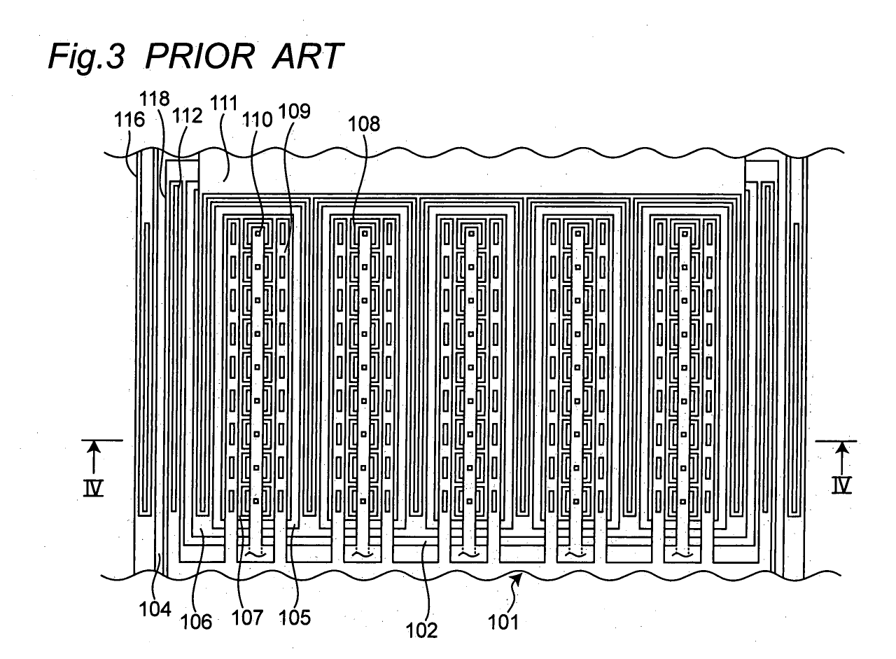

FIG. 4 is a sectional view taken along the line IV-IV of FIG. 3; and

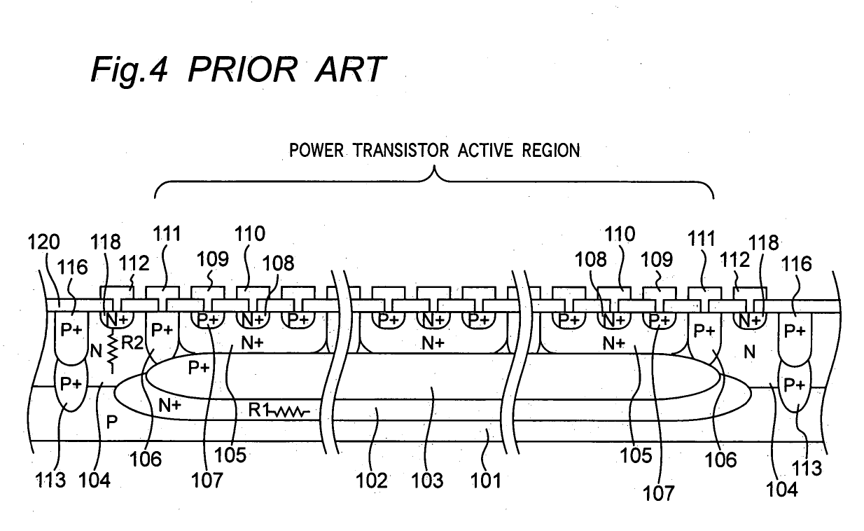

FIG. 5 is a view showing the cross-sectional structure of the vertical PNP transistor in the saturation region.

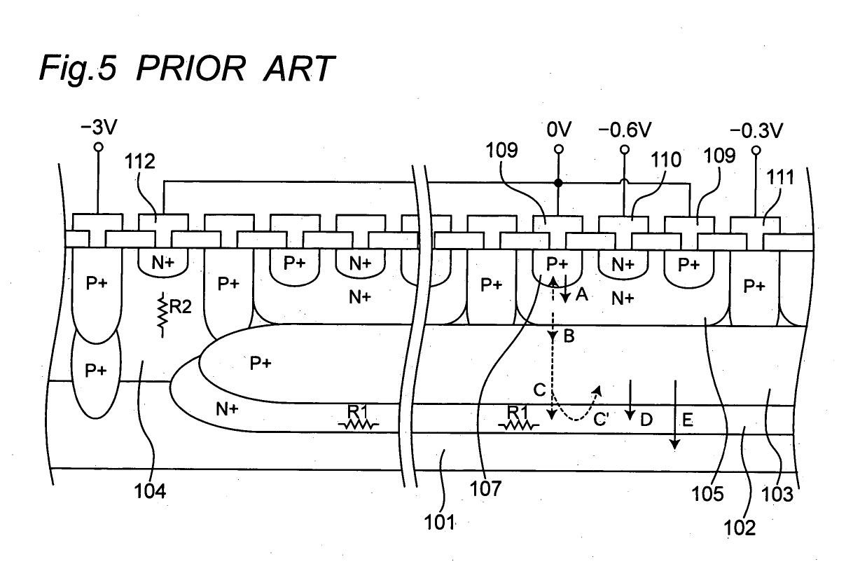

### DETAILED DESCRIPTION OF THE PREFERRED EMBODIMENTS

Hereinbelow, the power transistor of the present invention is described in detail by way of embodiments thereof illustrated in the accompanying drawings.

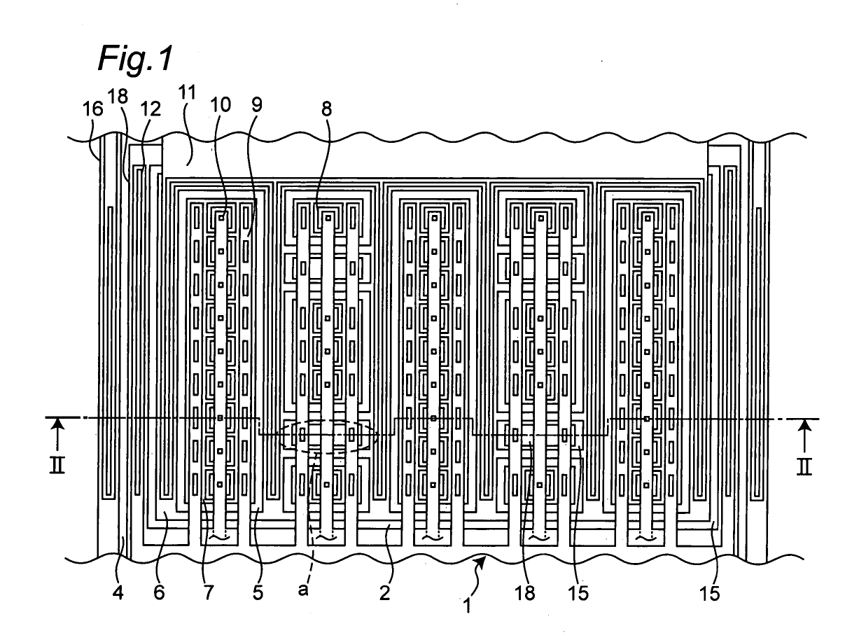

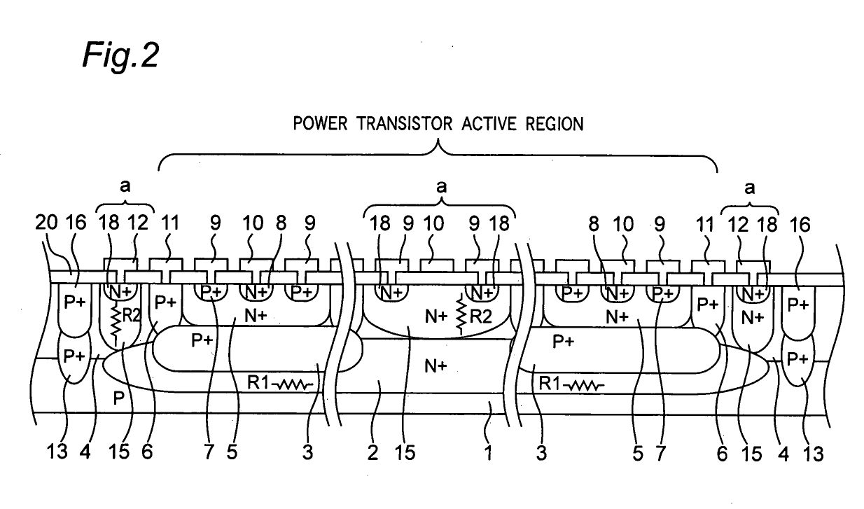

FIG. 1 is a pattern plan view of a power transistor according to an embodiment of the present invention, and FIG. 2 is a sectional view taken along the line II-II of FIG. 1.

In this power transistor, as shown in FIGS. 1 and 2., there are formed, on a P-type silicon substrate 1: an N⁺ type buried layer 2 for isolating the P-type silicon substrate 1 and a collector of each vertical PNP transistor from each other; a P⁺ type collector buried layer 3 which serves as the collector of each vertical PNP transistor; a P⁺ type buried isolation layer 13 formed around the N⁺ type buried layer 2 to isolate the power transistor and its peripheral devices from each other; a an N-type epitaxial layer 4 formed all over the surface of the P-type silicon substrate 1 by epitaxial growth; an N⁺ type base well layer 5 formed at a base region of each vertical PNP transistor to improve the transistor characteristics; an N⁺ type diffusion layer 15 formed at electrode portions ‘a’ of the N⁺ type buried layer 2 (just under an N⁺ type electrode layer 18) which are conventionally formed so as to surround the power transistor, as well as at electrode portions ‘a’ of an N⁺ type buried layer 2 within the active region of the power transistor in order to reduce the resistance of the N-type epitaxial layer 4; a P⁺ type collector layer 6 formed on the P⁺ type collector buried layer 3; a P⁺ type isolation layer 16 formed on the P⁺ type buried isolation layer 13 serving for device isolation; a P⁺ type emitter layer 7 serving as an emitter of each vertical PNP transistor formed within the region of the N⁺ type base well layer 5; and an N⁺ type base layer 8 formed in the base electrode region of each vertical PNP transistor.

Also, a selectively patterned and opened oxide film 20 is formed on the surface of the P-type silicon substrate 1, and further thereon are formed common emitter metal lines 9, common base metal lines 10 and common collector metal lines 11 which are routed for electrical connections among a plurality of unit transistors constituting the power transistor, as well as metal lines 12 of the N⁺ type buried layer 2 electrically connected to the common emitter metal lines 9 and grounded to GND. That is to say, the common emitter metal lines 9 are electrically connected to the metal lines 12, though not shown in FIG. 2.

It is noted that the electrode portions ‘a’ of the N⁺ type buried layer 2 formed within the active region of the power transistor are connected by the common emitter metal lines 9. This electrode portions ‘a’ are composed of the N⁺ type diffusion layer 15 and N⁺ type electrode layers 18 under the common emitter metal lines 9. The N⁺ type electrode layer 18 and the common emitter metal line 9 make ohmic contact. The power transistor of this invention is formed by a known standard bipolar IC manufacturing method. In FIG. 1, since the common base metal lines 10 are of less importance for the present invention, their interconnect lines are partly omitted.

With the power transistor of this construction, malfunctions of the parasitic PNP transistor, which have hitherto been an issue, can be prevented so that the leak current to the P-type silicon substrate 1 can be suppressed, and thus circuit malfunctions due to latch-up of the peripheral circuits of the power transistor can be prevented.

By experiments performed by the present inventor, it has been verified that the leak current of the power transistor designed based on this embodiment of the invention is improved to about 20%, compared to the conventional counterpart.

The plurality of electrode portions ‘a’ of the N⁺ type buried layer 2, which need to be equal in voltage level to the common emitter metal lines 9 of the power transistor, can be connected directly to the common emitter metal lines 9 formed and routed on the active region of the power transistor, effective use of the limited design space of the power transistor can be made, making it unnecessary to make complex pattern design.

Also, the N⁺ type diffusion layer 15 of the electrode portions ‘a’ of the N⁺ type buried layer 2 are formed simultaneously with the N⁺ type base well layer 5, so that dopants are diffused and formed at a dopant concentration level heavier than that of the N-type epitaxial layer 4 and until they reach the lower-portion N⁺ type buried layer 2. As a result of this, it becomes possible to reduce the resistance R2 ranging from the N⁺ type electrode layer 18 to the N⁺ type buried layer 2 provided at the bottom face of the power transistor.

Typically, the N-type epitaxial layer of a bipolar IC (Integrated Circuit) is formed generally at a specific resistance of 1 to 5 Ω·cm (dopant level: 1 to 5×10¹⁵ atoms/cm³). However, in consideration of the N⁺ type base well layer 5 that affects the characteristics of vertical PNP transistors, it is desirable that the N⁺ type diffusion layer 15 is formed at a dopant level within a range of 1×10¹⁶ to 1×10¹⁷ atoms/cm³.

Also, the electrode portions ‘a’ of the N⁺ type buried layer 2 (region of the N⁺ type electrode layer 18), which are conventionally formed around the power-transistor active region, and the plurality of electrode portions ‘a’ of the N⁺ type buried layer 2 provided within the active region, are placed so as to be spaced at shorter distances therebetween and arranged uniformly. As a result of this, the resistance R1 of the N⁺ type buried layer 2 just under the power transistor can be made smaller, and the resistance distribution of the N⁺ type buried layer 2 can be uniformized, thus making it possible to suppress the occurrence of local leak currents.

Further, although depending on the resistance value of the N⁺ type buried layer 2, hFE of the parasitic PNP transistors, and the like, the number of placed electrode portions ‘a’ of the N⁺ type buried layer 2, if required, can be increased to reduce the resistance R1.

Although the above embodiment has been described on a power transistor in which a plurality of vertical PNP transistors are formed on the P-type silicon substrate 1, the semiconductor substrate is not limited to silicon substrates and may be those made of other materials. Further, although the above embodiment has been described on a power transistor in which a plurality of electrode portions ‘a’ of the N⁺ type buried layer 2 are provided, yet the electrode portion ‘a’ may be given one in number, and the placement or number of the electrode portions ‘a’ may be set as required according to the construction of the vertical PNP transistors or the like.

Furthermore, using the power transistor of the above embodiment for integrated circuits makes it possible to implement a high-performance integrated circuit capable of stable operation.

As apparent from the above description, according to the power transistor of the present invention, by the provision of a plurality of electrode portions of the N⁺ type buried layer within the power-transistor active region, resistance over a range from the N⁺ type buried layer to the electrode layer can be reduced, so that malfunctions of the parasitic PNP transistors can be prevented, making it possible to suppress the leak currents to the P-type silicon substrate. Thus, circuit malfunctions due to latch-up of the peripheral circuits of the power transistor can be prevented.

Further, according to the semiconductor integrated circuit of the present invention, by using the above-described power transistor, a high-performance semiconductor integrated circuit capable of stable operation can be provided.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A power transistor composed of a plurality of vertical PNP transistors formed on a P-type silicon substrate, wherein
a singularity or plurality of electrode portions of an N⁺ type buried layer formed to isolate the P-type silicon substrate and the plurality of vertical PNP transistors from each other are provided in an active region of the power transistor.

2. The power transistor according to claim 1, wherein
at least part of the electrode portion is provided under common emitter metal lines of the power transistor routed on the active region of the power transistor.

3. The power transistor according to claim 1, wherein
the electrode portions are provided on the N⁺ type buried layer and formed of an N⁺ type electrode layer for making ohmic contact and an N⁺ type diffusion layer.

4. The power transistor according to claim 3, wherein
the N⁺ type diffusion layer is formed simultaneously with an N⁺ type base well layer as a base region of the plurality of vertical PNP transistors.

5. The power transistor according to claim 3, wherein
the N⁺ type diffusion layer is formed at a range of dopant level of 1×10¹⁶ to 1×10¹⁷ atoms/cm³, which is heavier than that of an N-type epitaxial layer formed on the P-type silicon substrate.

6. The power transistor according to claim 3, wherein
the N⁺ type diffusion layer is formed so that dopants are diffused until they reach the N⁺ type buried layer present on a bottom face of the power transistor.

7. The power transistor according to claim 1, wherein
the singularity or plurality of electrode portions are placed so as to be uniformly spaced from their respectively adjacent electrode portions.

8. A semiconductor integrated circuit characterized by using the power transistor as defined in claim 1.
